(19) United States
(12) Patent Application Publication
(10) Pub. No.: US 2016/0005888 A1
(43) Pub. Date: Jan. 7, 2016

(54) COMPOSITION FOR FORMING SOLAR CELL ELECTRODE AND ELECTRODE PRODUCED FROM SAME

(71) Applicant: CHEIL INDUSTRIES, INC., Gumi-si, Gyeongsangbuk-do (KR)

(72) Inventors: Dong Suk KIM, Uiwang-si, Gyeonggi-do (KR); Min Jae KIM, Uiwang-si, Gyeonggi-do (KR); Seok Hyun JUNG, Uiwang-si, Gyeonggi-do (KR); Dong Il SHIN, Uiwang-si, Gyeonggi-do (KR); Young Wook CHOI, Uiwang-si, Gyeonggi-do (KR)

(21) Appl. No.: 14/409,722

(22) PCT Filed: Oct. 31, 2013
(86) PCT No.: PCT/KR2013/009771

§ 371 Date: Dec. 19, 2014

(30) Foreign Application Priority Data
Mar. 27, 2013 (KR) 10-2013-0033030

(51) Int. Cl. H01L 31/0224

(52) U.S. Cl. CPC H01L 31/022425

(57) ABSTRACT

The present invention relates to a composition for solar cell electrodes, comprising: a silver powder; a bismuth oxide-tellurium oxide-tungsten oxide-zinc oxide-based glass frit; and an organic vehicle, wherein the glass fit comprises about 40 wt % to about 60 wt % of bismuth oxide; about 0.25 wt % to about 15 wt % of tellurium oxide; about 10 wt % to about 20 wt % of tungsten oxide; and about 2 wt % to about 20 wt % of zinc oxide, and solar cell electrodes formed of the composition for solar cell electrodes have excellent adhesive strength with respect to a ribbon and minimized serial resistance (Rs), thus providing high conversion efficiency.

### TECHNICAL FIELD

The present invention relates to a composition for solar cell electrodes and electrodes fabricated using the same.

### BACKGROUND ART

Solar cells generate electric energy using the photovoltaic effect of a p-n junction which converts photons of sunlight into electricity. In the solar cell, front and rear electrodes are formed on upper and lower surfaces of a semiconductor wafer or substrate with the p-n junction, respectively. Then, the photovoltaic effect of the p-n junction is induced by sunlight entering the semiconductor wafer and electrons generated by the photovoltaic effect of the p-n junction provide electric current to the outside through the electrodes. The electrodes of the solar cell are formed on the wafer by applying, patterning, and baking a composition for electrodes.

Continuous reduction in emitter thickness for improvement of solar cell efficiency can cause shunting which can deteriorate solar cell performance. In addition, solar cells have been gradually increased in area to achieve high efficiency. In this case, however, there can be a problem of efficiency deterioration due to increase in contact resistance of the solar cell.

Solar cells are connected to each other by a ribbon to constitute a solar cell battery. In this case, low adhesion between electrodes and the ribbon can cause large serial resistance and deterioration in conversion efficiency. The inventors of the present invention developed a composition for solar cells based on the fact that solar cell electrodes fabricated using a typical composition including lead glass frits exhibit insufficient adhesive strength with respect to the ribbon.

### DISCLOSURE

### Technical Problem

An object of the present invention is to provide a composition for solar cell electrodes having excellent adhesive strength with respect to ribbons.

Another object of the present invention is to provide a composition for solar cell electrodes capable of minimizing serial resistance (Rs).

A further object of the present invention is to provide a composition for solar cell electrodes having high conversion efficiency.

The aforementioned and other objects of the present invention will be achieved by the present invention as described below.

### Technical Solution

In accordance with one aspect of the invention, a composition for solar cell electrodes includes: a silver powder; a bismuth oxide-tellurium oxide-tungsten oxide-zinc oxide-based glass frit; and an organic vehicle, wherein the glass frit includes about 40% by weight (wt %) to about 60 wt % of bismuth oxide; 0.25 about wt % to about 15 wt % of tellurium oxide; about 10 wt % to about 20 wt % of tungsten oxide; and about 2 wt % to about 20 wt % of zinc oxide.

The glass frit may further include at least one metal oxide selected from the group consisting of lithium oxide (Li₂O), vanadium oxide (V₂O₅), phosphorous oxide (P₂O₅), magnesium oxide (MgO), cerium oxide (CeO₂), boron oxide (B₂O₃), strontium oxide (SrO), molybdenum oxide (MoO₃), titanium oxide (TiO₂), tin oxide (SnO), indium oxide (In₂O₃), barium oxide (BaO), nickel oxide (NiO), copper oxide (Cu₂O or CuO), sodium oxide (Na₂O), potassium oxide (K₂O), antimony oxide (Sb₂O₃, Sb₂O₄ or Sb₂O₅), germanium oxide (GeO₂), gallium oxide (Ga₂O₃), calcium oxide (CaO), arsenic oxide (As₂O₃), cobalt oxide (CoO or Co₂O₃), zirconium oxide (ZrO₂), manganese oxide (MnO, Mn₂O₃ or Mn₃O₄), and aluminum oxide (Al₂O₃).

The composition may include about 60 wt % to about 95 wt % of the silver powder; about 0.5 wt % to about 20 wt % of the bismuth oxide-tellurium oxide-tungsten oxide-zinc oxide-based glass frit; and about 1 wt % to about 30 wt % of the organic vehicle.

The glass frit may have an average particle diameter (D50) of about 0.1 μm to about 10 μm.

The composition may further include at least one additive selected from the group consisting of dispersants, thixotropic agents, plasticizers, viscosity stabilizers, anti-foaming agents, pigments, UV stabilizers, antioxidants, and coupling agents.

In accordance with another aspect of the present invention, there is provided a solar cell electrode formed using the composition for solar cell electrodes.

### Advantageous Effects

Solar cell electrodes fabricated using a composition for solar cell electrodes of the present invention have excellent adhesive strength with respect to ribbons and minimize serial resistance (Rs), thereby providing excellent conversion efficiency.

### DESCRIPTION OF DRAWING

FIG. 1 is a schematic view of a solar cell manufactured using a composition in accordance with one embodiment of the present invention.

### BEST MODE

Composition for Solar Cell Electrodes

A composition for solar cell electrodes according to the invention includes a silver powder; a bismuth oxide-tellurium oxide-tungsten oxide-zinc oxide-based glass frit; and an organic vehicle. The composition exhibits high adhesion with respect to a ribbon connecting solar cells to each other and minimizes serial resistance (Rs), thereby providing excellent conversion efficiency.

Now, the present invention will be described in more detail.

(A) Silver Powder

The composition for solar cell electrodes according to the invention includes silver powder as a conductive powder. The particle size of the silver powder may be on a nanometer or micrometer scale. For example, the silver powder may have a particle size of dozens to several hundred nanometers, or several to dozens of micrometers. Alternatively, the silver powder may be a mixture of two or more types of silver powders having different particle sizes.

The silver powder may have a spherical, flake or amorphous shape.

The silver powder preferably has an average particle diameter (D50) of about 0.1 μm to about 10 μm, more preferably about 0.5 μm to about 5 μm. The average particle diameter may be measured using, for example, a Model 1064D (CILAS Co., Ltd.) after dispersing the conductive powder in isopropyl alcohol (IPA) at 25° C. for 3 minutes via ultrasonication. Within this range of average particle diameter, the composition can provide low contact resistance and low line resistance.

The silver powder may be present in an amount of about about 60 wt % to about 95 wt % based on the total weight of the composition. Within this range, the conductive powder can prevent deterioration in conversion efficiency due to increase in resistance. Advantageously, the conductive powder is present in an amount of about 70 wt % to about 90 wt %.

(B) Bismuth oxide-tellurium oxide-tungsten oxide-zinc oxide-Based Glass Frit

The glass frit serves to enhance adhesion between the conductive powder and the wafer or the substrate and to form silver crystal grains in an emitter region by etching an anti-reflection layer and melting the silver powder so as to reduce contact resistance during a baking process of the electrode paste. Further, during the baking process, the glass frit is softened and decreases the baking temperature.

When the area of the solar cell is increased in order to improve solar cell efficiency, there can be a problem of increase in contact resistance of the solar cell. Thus, it is necessary to minimize serial resistance (Rs) and influence on the p-n junction. In addition, as the baking temperatures varies within a broad range with increasing use of various wafers having different sheet resistances, it is desirable that the glass frit secure sufficient thermal stability to withstand a wide range of baking temperatures.

Solar cells are connected to each other by a ribbon to constitute a solar cell battery. In this case, low adhesive strength between solar cell electrodes and the ribbon can cause detachment of the cells or deterioration in reliability. In this invention, in order to ensure that the solar cell has desirable electrical and physical properties such as adhesive strength, a bismuth oxide-tellurium oxide-tungsten oxide-zinc oxide-based (Bi₂O₃—TeO₂—WO₃—ZnO) lead-free glass frit is used.

In the present invention, the bismuth oxide-tellurium oxide-tungsten oxide-zinc oxide-based glass frit may contain about 40 wt % to about 60 wt % of bismuth oxide; about 0.25 wt % to about 15 wt % of tellurium oxide, about 10 wt % to about 20 wt % of tungsten oxide, and about 2 wt % to about 20 wt % of zinc oxide. Within this range, the glass frit can secure both excellent adhesive strength and excellent conversion efficiency.

In one embodiment, the bismuth oxide-tellurium oxide-tungsten oxide-zinc oxide-based glass frit may further include at least one metal oxide selected from the group consisting of lithium oxide (Li₂O), vanadium oxide (V₂O₅), phosphorous oxide (P₂O₅), magnesium oxide (MgO), cerium oxide (CeO₂), boron oxide (B₂O₃), strontium oxide (SrO), molybdenum oxide (MoO₃), titanium oxide (TiO₂), tin oxide (SnO), indium oxide (In₂O₃), barium oxide (BaO), nickel oxide (NiO), copper oxide (Cu₂O or CuO), sodium oxide (Na₂O), potassium oxide (K₂O), antimony oxide (Sb₂O₃, Sb₂O₄ or Sb₂O₅), germanium oxide (GeO₂), gallium oxide (Ga₂O₃), calcium oxide (CaO), arsenic oxide (As₂O₃), cobalt oxide (CoO or Co₂O₃), zirconium oxide (ZrO₂), manganese oxide (MnO, Mn₂O₃ or Mn₃O₄), and aluminum oxide (Al₂O₃).

The glass frit may be prepared from such metal oxides by any typical method. For example, the metal oxides may be mixed in a predetermined ratio. Mixing may be carried out using a ball mill or a planetary mill. The mixed composition is melted at about 900° C. to about 1300° C., followed by quenching to about 25° C. The resulting material is subjected to pulverization using a disk mill, a planetary mill, or the like, thereby providing a glass frit.

The glass frit may have an average particle diameter D50 of about 0.1 μm to about 10 μm, and may be present in an amount of about 0.5 wt % to about 20 wt % based on the total amount of the composition. The glass frit may have a spherical or amorphous shape.

(C) Organic Vehicle

The organic vehicle imparts suitable viscosity and rheological characteristics for printing to the paste composition through mechanical mixing with the inorganic component of the composition for solar cell electrodes.

The organic vehicle may be any typical organic vehicle used for the composition for solar cell electrodes, and may include a binder resin, a solvent, and the like.

The binder resin may be selected from acrylate resins or cellulose resins. Ethyl cellulose is generally used as the binder resin. In addition, the binder resin may be selected from among ethyl hydroxyethyl cellulose, nitrocellulose, blends of ethyl cellulose and phenol resins, alkyd, phenol, acrylate ester, xylene, polybutane, polyester, urea, melamine, vinyl acetate resins, wood rosin, polymethacrylates of alcohols, and the like.

The solvent may be selected from the group consisting of, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, ethyl lactate, and combinations thereof.

The organic vehicle may be present in an amount of about 1 wt % to about 30 wt % based on the total weight of the composition. Within this range, the organic vehicle can provide sufficient adhesive strength and excellent printability to the composition.

(D) Additives

The composition may further include typical additives, as needed, to enhance flow properties, process properties, and stability. The additives may include dispersants, thixotropic agents, plasticizers, viscosity stabilizers, anti-foaming agents, pigments, UV stabilizers, antioxidants, coupling agents, and the like, without being limited thereto. These additives may be used alone or as mixtures thereof. These additives may be present in an amount of about 0.1 wt % to about 5 wt % in the composition, but this amount may be changed as needed.

Solar Cell Electrode and Solar Cell Including the Same

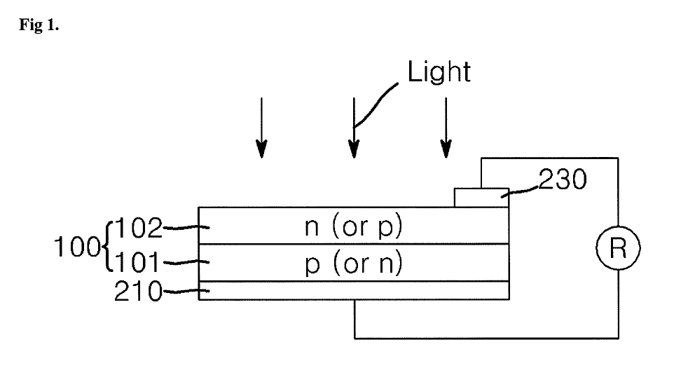

Other aspects of the present invention relate to an electrode formed of the composition for solar cell electrodes and a solar cell including the same. FIG. 1 shows a solar cell in accordance with one embodiment of the present invention.

Referring to FIG. 1, a rear electrode 210 and a front electrode 230 may be formed by printing and baking the composition on a wafer or substrate 100 that includes a p-layer 101 and an n-layer 102, which will serve as an emitter. For example, a preliminary process for preparing the rear electrode is performed by printing the composition on the rear surface of the wafer and drying the printed composition at about 200° C. to about 400° C. for about 10 seconds to 60 seconds. Further, a preliminary process for preparing the front electrode may be performed by printing the paste on the front surface of the wafer and drying the printed composition. Then, the front electrode and the rear electrode may be formed by baking the wafer at about 400° C. to about 950° C., preferably at about 850° C. to about 950° C., for about 30 seconds to 50 seconds.

Next, the present invention will be described in more detail with reference to examples. However, it should be noted that these examples are provided for illustration only and should not be construed in any way as limiting the invention.

### Mode for Invention

### EXAMPLES

### Example 1

Metal oxides were mixed according to the compositions listed in Table 1 and subjected to melting and sintering at 900° C. to 1400° C., thereby preparing bismuth oxide-tellurium oxide-tungsten oxide-zinc oxide-based glass frits having an average particle diameter (D50) of 1.7 μm.

As an organic binder, 0.8 wt % of ethylcellulose (STD4, Dow Chemical Company) was sufficiently dissolved in 9.0 wt % of butyl carbitol at 60° C., and 86 wt % of spherical silver powder (AG-4-8, Dowa Hightech Co. Ltd.) having an average particle diameter of 2.0 μm, 3.5 wt % of the prepared bismuth oxide-tellurium oxide-tungsten oxide-zinc oxide-based glass frits, 0.2 wt % of a dispersant BYK102 (BYK-chemie) and 0.5 wt % of a thixotropic agent Thixatrol ST (Elementis Co., Ltd.) were added to the binder solution, followed by mixing and kneading in a 3-roll kneader, thereby preparing a composition for solar cell electrodes.

The prepared composition was deposited over a front surface of a crystalline mono-wafer by screen-printing in a predetermined pattern, followed by drying in an IR drying furnace. Then, the composition for electrodes containing aluminum was printed on a rear side of the wafer and dried in the same manner. Cells formed according to this procedure were subjected to baking at 910° C. for 40 seconds in a belt-type baking furnace, and evaluated as to conversion efficiency (%), serial resistance Rs (mΩ) and open voltage (Voc) using a solar cell efficiency tester CT-801 (Pasan Co., Ltd.). Then, flux was applied to the electrodes of the cells and bonded to a ribbon at 300° C. to 400° C. using a soldering iron (Hakko Co., Ltd.). Then, the resultant was evaluated as to adhesive strength (N/mm) at a peeling angle of 180° and a stretching rate of 50 mm/min using a tensioner (Tinius Olsen). The measured conversion efficiency, serial resistance, open voltage and adhesive strength are shown in Table 1.

### Example 2 to 5 and Comparative Example 1 to 9

Compositions for solar cell electrodes were prepared and evaluated as to physical properties in the same manner as in Example 1 except that the glass frits were prepared in compositions as listed in Table 1. Results are shown in Table 1.

TABLE 1

| | | | | | | | | | Adhesive | | Conversion |
|---|---|---|---|---|---|---|---|---|---|---|---|
| | Composition of glass frit (unit: wt %) | | | | | | | | Strength | Rs | efficiency |
| | PbO | Bi₂O₃ | TeO₂ | WO₃ | ZnO | B₂O₃ | Li₂O | V₂O₅ | (N/mm) | (mΩ) | (%) |
| Example 1 | — | 55 | 15 | 16 | 4 | — | 2 | 8 | 4.16 | 0.0054 | 17.671 |
| Example 2 | — | 58 | 12 | 17 | 7 | | 2 | 4 | 5.08 | 0.0051 | 17.711 |
| Example 3 | — | 60 | 13 | 15 | 11 | | 1 | 0 | 4.89 | 0.0051 | 17.719 |
| Example 4 | — | 58 | 12 | 15 | 13 | — | 1 | 1 | 5.12 | 0.0053 | 17.675 |
| Example 5 | — | 60 | 10 | 14 | 15 | | 1 | 0 | 5.15 | 0.0065 | 17.323 |
| Comparative | 40 | | 30 | 30 | — | — | — | — | 2.31 | 0.0058 | 17.6231 |
| Example 1 | | | | | | | | | | | |
| Comparative | — | 35 | 15 | 15 | — | 10 | 1 | 24 | 1.78 | 0.0061 | 17.4862 |
| Example 2 | | | | | | | | | | | |
| Comparative | — | 70 | 12 | 14 | — | — | 1 | 3 | 2.69 | 0.0067 | 17.4106 |
| Example 3 | | | | | | | | | | | |
| Comparative | — | 60 | 0 | 19 | — | — | 1 | 20 | 3.13 | 0.0059 | 17.5914 |
| Example 4 | | | | | | | | | | | |
| Comparative | — | 55 | 20 | 10 | — | — | 1 | 14 | 2.23 | 0.0058 | 17.702 |
| Example 5 | | | | | | | | | | | |
| Comparative | — | 60 | 15 | 8 | — | — | 1 | 16 | 1.20 | 0.0055 | 17.66 |
| Example 6 | | | | | | | | | | | |
| Comparative | — | 60 | 15 | 22 | — | — | 1 | 2 | 1.89 | 0.0053 | 17.67 |
| Example 7 | | | | | | | | | | | |
| Comparative | — | 59 | 13 | 18 | 0.5 | — | 1 | 8.5 | 2.00 | 0.0065 | 17.425 |
| Example 8 | | | | | | | | | | | |
| Comparative | — | 55 | 7 | 13 | 21 | — | 1 | 3 | 4.83 | 0.0071 | 17.012 |
| Example 9 | | | | | | | | | | | |

As shown in Table 1, it can be seen that the solar cell electrodes fabricated using the compositions prepared in Examples 1 to 5 exhibited considerably high adhesive strength to the ribbons as well as low serial resistance and excellent conversion efficiency, as compared with the solar cell of Comparative Example 1 wherein a leaded glass frit was used, and the solar cells of Comparative Examples 2 to 9 wherein the compositions of the glass frits did not satisfy the present invention.

Although some embodiments have been described, it will be apparent to those skilled in the art that these embodiments are given by way of illustration only, and that various modifications, changes, alterations, and equivalent embodiments can be made without departing from the spirit and scope of the invention. The scope of the invention should be limited only by the accompanying claims and equivalents thereof.

1. A composition for solar cell electrodes, comprising: a silver powder, a bismuth oxide-tellurium oxide-tungsten oxide-zinc oxide-based glass frit; and an organic vehicle, wherein the glass frit comprises about 40 wt % to about 60 wt % of bismuth oxide; about 0.25 wt % to about 15 wt % of tellurium oxide; about 10 wt % to about 20 wt % of tungsten oxide; and about 2 wt % to about 20 wt % of zinc oxide.

2. The composition according to claim 1, wherein the glass frit further comprises at least one metal oxide selected from the group consisting of lithium oxide (Li₂O), vanadium oxide (V₂O₅), phosphorous oxide (P₂O₅), magnesium oxide (MgO), cerium oxide (CeO₂), boron oxide (B₂O₃), strontium oxide (SrO), molybdenum oxide (MoO₃), titanium oxide (TiO₂), tin oxide (SnO), indium oxide (In₂O₃), barium oxide (BaO), nickel oxide (NiO), copper oxide (Cu₂O or CuO), sodium oxide (Na₂O), potassium oxide (K₂O), antimony oxide (Sb₂O₃, Sb₂O₄ or Sb₂O₅), germanium oxide (GeO₂), gallium oxide (Ga₂O₃), calcium oxide (CaO), arsenic oxide (As₂O₃), cobalt oxide (CoO or Co₂O₃), zirconium oxide (ZrO₂), manganese oxide (MnO, Mn₂O₃ or Mn₃O₄), and aluminum oxide (Al₂O₃).

3. The composition according to claim 1, comprising: about 60 wt % to about 95 wt % of the silver powder; about 0.5 wt % to about 20 wt % of the bismuth oxide-tellurium oxide-tungsten oxide-zinc oxide-based glass fit; and about 1 wt % to about 30 wt % of the organic vehicle.

4. The composition according to claim 1, wherein the glass frit has an average particle diameter (D50) of about 0.1 μm to about 10 μm.

5. The composition according to claim 1, further comprising: at least one selected from the group consisting of dispersants, thixotropic agents, plasticizers, viscosity stabilizers, anti-foaming agents, pigments, UV stabilizers, antioxidants, and coupling agents.

6. A solar cell electrode prepared from the composition for solar cell electrodes according to claim 1.
